(19) United States
(12) Patent Application Publication
(10) Pub. No.: US 2024/0321753 A1
(43) Pub. Date: Sep. 26, 2024

(54) PACKAGE SUBSTRATE AND SEMICONDUCTOR PACKAGE INCLUDING THE SAME

(71) Applicant: Samsung Electronics Co., Ltd., Suwon-si (KR)

(72) Inventor: Okgyeong PARK, Suwon-si (KR)

(73) Assignee: Samsung Electronics Co., Ltd., Suwon-si (KR)

(21) Appl. No.: 18/606,843

(22) Filed: Mar. 15, 2024

(30) Foreign Application Priority Data
Mar. 24, 2023 (KR) 10-2023-0039189
Jun. 7, 2023 (KR) 10-2023-0073143

(51) Int. Cl. H01L 23/538; H01L 23/00; H01L 23/48; H01L 23/498; H01L 25/065; H01L 25/10; H10B 80/00

(52) U.S. Cl. CPC H01L 23/5383; H01L 23/481; H01L 23/49816; H01L 23/49827; H01L 23/5381; H01L 25/105; H01L 24/16; H01L 24/32; H01L 24/73; H01L 25/0657; H01L 2224/16145; H01L 2224/16227; H01L 2224/32145; H01L 2224/32225; H01L 2224/73204; H10B 80/00

(57) ABSTRACT

A package substrate may include a core substrate including a first surface and a second surface, a first core laminated structure on the first surface of the core substrate, including first core insulating layers and first cores wiring layers on the first core insulating layers, and including a first chip mounting space defined by the first core insulating layers, a bridge chip within the first chip mounting space and including a bridge substrate and a bridge pad, and a second core laminated structure on the second surface of the core substrate, and including second core insulating layers and second core wiring layers on the second core insulating layers, wherein the first core insulating layers have a first coefficient of thermal expansion, and the second core insulating layers have a second coefficient of thermal expansion less than the first coefficient of thermal expansion.

### CROSS-REFERENCES TO RELATED APPLICATION

This application is based on and claims priority under 35 U.S.C. § 119 to Korean Patent Application Nos. 10-2023-0039189, filed on Mar. 24, 2023, and 10-2023-0073143, filed on Jun. 7, 2023 in the Korean Intellectual Property Office, the disclosures of each of which are incorporated by reference herein in their entirety.

### BACKGROUND

The inventive concepts relate to package substrates and/or semiconductor packages including the same, and more particularly, to package substrates including a bridge chip and/or semiconductor packages including the same.

In accordance with the rapid development of the electronics industry and the needs of users, electronic devices are becoming more miniaturized and lightweight, and semiconductor packages used in electronic devices are required to have high performance and large capacity along with miniaturization and lightweight. In order to realize high performance and large capacity along with miniaturization and light weight, research and development on a package substrate including a bridge chip, and a semiconductor package including the bridge chip, are continuously being conducted.

### SUMMARY

Some example embodiments of the inventive concepts provide package substrates with reduced warpage problems even when a bridge chip is included and/or semiconductor packages including the same.

According to an aspect of the inventive concepts, a package substrate may include a core substrate including a first surface and a second surface opposite to the first surface, a first core laminated structure on the first surface of the core substrate, including a plurality of first core insulating layers and a plurality of first cores wiring layers on the plurality of first core insulating layers, and including a first chip mounting space defined by the plurality of first core insulating layers, a bridge chip within the first chip mounting space and including a bridge substrate and a bridge pad, and a second core laminated structure on the second surface of the core substrate, and including a plurality of second core insulating layers and a plurality of second core wiring layers on the plurality of second core insulating layers, wherein the first core insulating layer has a first coefficient of thermal expansion, and the second core insulating layer has a second coefficient of thermal expansion less than the first coefficient of thermal expansion.

According to another aspect of the inventive concepts, a package substrate may include a core substrate including a first surface and a second surface opposite to the first surface, a first core laminated structure on the first surface of the core substrate, including a plurality of first core insulating layers including a first insulating material having a first coefficient of thermal expansion, and including a plurality of first core wiring layers forming an upper conductive path that is electrically connected to the core substrate, a second core laminated structure on the second surface of the core substrate, and including a plurality of second core insulating layers including a second insulating material having a second coefficient of thermal expansion less than the first coefficient of thermal expansion and a plurality of second core wiring layers forming a lower conductive path electrically connected to the core substrate, and a bridge chip in a first chip mounting space defined in an upper portion of the first core laminated structure and including a bridge substrate and a bridge pad, the bridge pad electrically connected to the upper conductive path.

According to an aspect of the inventive concepts, a semiconductor package may include a package substrate, and a first semiconductor chip and a second semiconductor chip mounted on the package substrate, wherein the package substrate includes a core substrate including a first surface and a second surface opposite to the first surface, a first core laminated structure on the first surface of the core substrate, including a plurality of first core insulating layers and a plurality of first core wirings on the plurality of first core insulating layers, and including a first chip mounting space defined by the plurality of first core insulating layers, a bridge chip within the first chip mounting space and including a bridge substrate and a bridge pad, and a second core laminated structure on the second surface of the core substrate, and including a plurality of second core insulating layers and a plurality of second core wiring layers on the plurality of second core insulating layers, wherein the first core insulating layer has a first coefficient of thermal expansion, and the second core insulating layer has a second coefficient of thermal expansion less than the first coefficient of thermal expansion, and the first semiconductor chip and the second semiconductor chip are electrically connected to each other through the bridge chip.

### BRIEF DESCRIPTION OF THE DRAWINGS

Example embodiments will be more clearly understood from the following detailed description taken in conjunction with the accompanying drawings in which:

FIG. 1 is a plan view illustrating a package substrate according to an example embodiment;

FIG. 2 is a cross-sectional view taken along line A-A′ of FIG. 1;

FIG. 3 is an enlarged view of part B of FIG. 2;

FIG. 4 is a cross-sectional view illustrating a package substrate according to an example embodiment;

FIG. 5 is an enlarged view of part B of FIG. 4;

FIG. 6 is a cross-sectional view illustrating a package substrate according to an example embodiment;

FIG. 7 is a cross-sectional view illustrating a package substrate according to an example embodiment;

FIG. 8 is a cross-sectional view illustrating a package substrate according to an example embodiment;

FIG. 9 is a plan layout illustrating a semiconductor package according to an example embodiment;

FIG. 10 is a cross-sectional view taken along line A-A′ of FIG. 9;

FIG. 11 is a cross-sectional view illustrating a semiconductor package according to an example embodiment;

FIG. 12 is a cross-sectional view illustrating a semiconductor package according to an example embodiment;

FIG. 13 is a cross-sectional view illustrating a semiconductor package according to an example embodiment.

FIG. 14 is a cross-sectional view illustrating a semiconductor package according to an example embodiment;

FIG. 15 is a schematic diagram illustrating warpage simulation of a package substrate according to a Comparative Example; and

FIGS. 16A and 16B are warpage simulation mapping diagrams of a package substrate according to a Comparative Example.

### DETAILED DESCRIPTION

Hereinafter, some example embodiments of the inventive concepts will be described in detail with reference to the accompanying drawings.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination of two or more of A, B, and C. Likewise, A and/or B means A, B, or A and B.

While the term “same” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” is used in this specification in connection with a numerical value, it is intended that the associated numerical value includes a manufacturing or operational tolerance (e.g., ±10%) around the stated numerical value. Moreover, when the word “generally” or “substantially” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

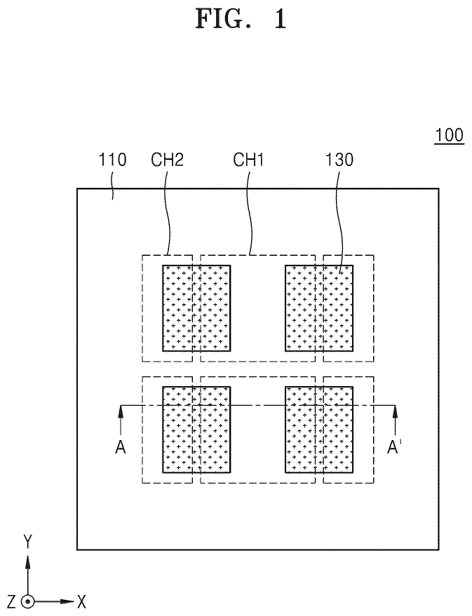

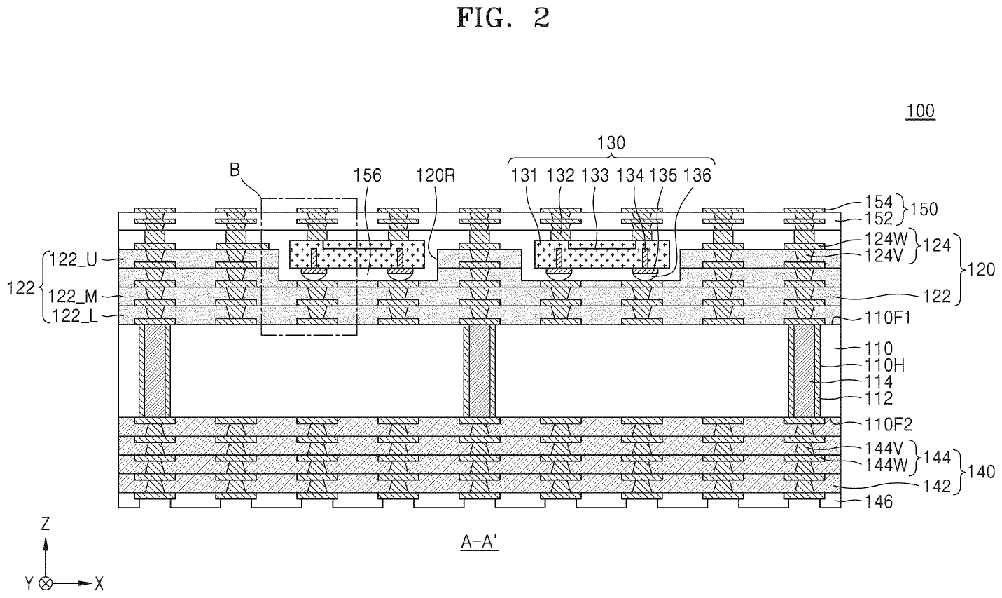

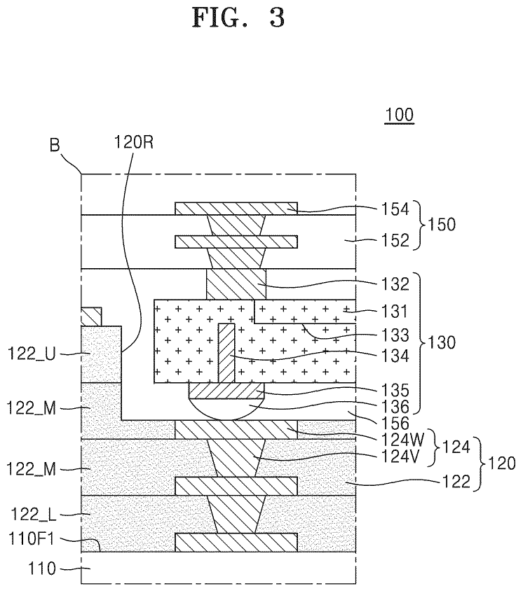

FIG. 1 is a plan view illustrating a package substrate 100 according to an example embodiment. FIG. 2 is a cross-sectional view taken along line A-A′ of FIG. 1. FIG. 3 is an enlarged view of part B of FIG. 2.

Referring to FIGS. 1 to 3, the package substrate 100 may include a core substrate 110, a first core laminated structure 120, a bridge chip 130, a second core laminated structure 140, and a redistribution structure 150.

As shown in FIG. 1, the package substrate 100 may be configured such that a first semiconductor chip CH1 and a second semiconductor chip CH2 are mounted on a central portion of the package substrate 100 from a plan view. The package substrate 100 may include a bridge chip 130 disposed at a position vertically overlapping both a portion of the first semiconductor chip CH1 and a portion of the second semiconductor chip CH2. For example, the first semiconductor chip CH1 may be disposed at a position partially overlapping the bridge chip 130 and the second semiconductor chip CH2 may be disposed at a position partially overlapping the bridge chip 130. The first semiconductor chip CH1 and the second semiconductor chip CH2 may be electrically connected to each other through the bridge chip 130. For example, a portion of the first semiconductor chip CH1 may vertically overlap a portion of the bridge chip 130, and a portion of the second semiconductor chip CH2 may vertically overlap another portion of the bridge chip 130.

The core substrate 110 may include a first surface 110F1 and a second surface 110F2 opposite to the first surface 110F1. A through hole 110H penetrating the core substrate 110 from the first surface 110F1 to the second surface 110F2 of the core substrate 110 is disposed, and a conductive layer 112 and a conductive via 114 may be disposed in the through hole 110H. The conductive layer 112 and the conductive via 114 may provide an electrical path through the through hole 110H.

In some example embodiments, the core substrate 110 may include an insulating substrate. For example, the core substrate 110 may include at least one of epoxy resin, glass fiber, glass cloth, prepreg, or filler. The conductive layer 112 and the conductive via 114 may include at least one of copper, nickel, tungsten, silver, or an alloy thereof.

A first core laminated structure 120 may be disposed on the first surface 110F1 of the core substrate 110. The first core laminated structure 120 may include a plurality of first core insulating layers 122 and a plurality of first core wiring layers 124. In some example embodiments, the plurality of first core insulating layers 122 may include at least one of an Ajinomoto build-up film (ABF), benzocyclo-buthene (BCB), photo imageable dielectric (PID), photosensitive polyimide (PSPI), solder resist, an epoxy molding compound (EMC), flame retardant 4 (FR-4), or bismaleimide triazine (BT).

The plurality of first core wiring layers 124 may be disposed between each of the plurality of first core insulating layers 122 and covered by the plurality of first core insulating layers 122. The plurality of first core wiring layers 124 may form upper conductive paths electrically connected to the core substrate 110 and each may include a via portion 124V and a wiring portion 124 W. A respective wiring portion 124 W may extend in a horizontal direction between a corresponding pair of the plurality of first core insulating layers 122 and may be disposed on a corresponding one of a plurality of vertical levels. The via portion 124V may be disposed inside via holes penetrating the plurality of first core insulating layers 122 and may connect the wiring portions 124 W to each other between the wiring portions 124 W disposed at different vertical levels. In some example embodiments, the via portion 124V and the wiring portion 124 W may include at least one of copper (Cu), nickel (Ni), chromium (Cr), titanium (Ti), gold (Au), platinum (Pt), silver (Ag), or tungsten (W).

The first core laminated structure 120 may include a first chip mounting space 120R defined above the first core laminated structure 120. In some example embodiments, the first chip mounting space 120R may refer to a cavity formed by removing portions of the plurality of first core insulating layers 122. The first chip mounting space 120R is disposed at a level corresponding to an upper portion of the first core laminated structure 120. For example, the first chip mounting space 120R may be spaced apart from the first surface 110F1 of the core substrate 110 in the vertical direction Z.

As shown in FIG. 3, the plurality of first core insulating layers 122 may include a lowermost core insulating layer 122_L, an uppermost core insulating layer 122_U, and at least one middle core insulating layer 122_M. The lowermost core insulating layer 122_L may refer to a layer disposed on the first surface 110F1 of the core substrate 110 and disposed closest to the core substrate 110. The uppermost core insulating layer 122_U may be disposed farthest from the first surface 110F1 of the core substrate 110. The at least one middle core insulating layer 122_M may refer to a layer disposed between the lowermost core insulating layer 122_L and the uppermost core insulating layer 122_U.

In some example embodiments, the first chip mounting space 120R may be formed by removing a portion of the uppermost core insulating layer 122_U and an upper portion of the at least one middle core insulating layer 122_M, and thus, the uppermost core insulating layer 122_U may be exposed at a side of the first chip mounting space 120R. Also, the at least one middle core insulating layer 122_M may be exposed at a bottom of the first chip mounting space 120R.

In some example embodiments, the plurality of first core insulating layers 122 may have a first coefficient of thermal expansion. Here, the first coefficient of thermal expansion may be expressed in a unit of a linear coefficient of thermal expansion, that is, a unit of ppm/K or ppm/° C., which is a unit of length change rate according to temperature change. For example, in some specific example embodiments, the first coefficient of thermal expansion may be in a range from about 5 ppm/° C. to about 30 ppm/° C. In some other example embodiments, the first coefficient of thermal expansion may be in a range from about 1 ppm/° C. to about 50 ppm/° C. However, the first coefficient of thermal expansion may be expressed as a volumetric coefficient of thermal expansion, which is a unit of rate of volume change according to temperature change, and in this case, the volumetric coefficient of thermal expansion may correspond to a value approximately three times the value expressed as a linear coefficient of thermal expansion.

The bridge chip 130 may be mounted in the first chip mounting space 120R. The bridge chip 130 may be configured to be electrically connected to the wiring portion 124 W disposed at the bottom of the first chip mounting space 120R in the first chip mounting space 120R. The bridge chip 130 may include a bridge substrate 131, a bridge pad 132, a bridge wiring 133, a bridge through-via 134, a bridge lower pad 135, and a bridge lower connection member 136.

In some example embodiments, the bridge substrate 131 may include a silicon substrate. In some example embodiments, the bridge substrate 131 may have a second coefficient of thermal expansion, and the second coefficient of thermal expansion may be less than the first coefficient of thermal expansion. For example, in some specific example embodiments, the second coefficient of thermal expansion may be in a range from about 1 ppm/° C. to about 10 ppm/° C.

In some example embodiments, the bridge pad 132 may be provided on a top of the bridge chip 130. The bridge wiring 133 may be disposed on an upper surface or at an upper portion of the bridge substrate 131, and the through-bridge via 134 may be disposed through the bridge substrate 131. The bridge lower pad 135 may be disposed on a lower surface of the bridge substrate 131. Although not specifically illustrated in the drawings (e.g., FIG. 3), the bridge lower pad 135 may be electrically connected to the bridge wiring 133 and/or the bridge pad 132 through the bridge through-via 134. The bridge lower pad 135 may be electrically connected to the wiring portion 124 W disposed on the bottom of the first chip mounting space 120R through the bridge lower connection member 136.

In some example embodiments, each of the bridge pad 132, the bridge wiring 133, the bridge through-via 134, and the bridge lower pad 135 may include a conductive material including at least one of copper (Cu), nickel (Ni), chromium (Cr), titanium (Ti), gold (Au), platinum (Pt), silver (Ag), or tungsten (W), and the bridge lower connection member 136 may include a bump or a solder ball.

In some example embodiments, the bridge chip 130 may not include a semiconductor device. The bridge chip 130 may include only a back end of line (BEOL) including the bridge wiring 133 disposed on the upper surface (e.g., at an upper portion) of the bridge substrate 131, and may not include a front end of line (FEOL) on which a semiconductor device is formed. The bridge chip 130 is configured so that the first semiconductor chip CH1 and the second semiconductor chip CH2 to be mounted on the package substrate 100 are electrically connected to each other through the bridge pad 132 and the bridge wiring 133. For example, the bridge wiring 133 may provide an electrical path between the bridge pad 132 to be connected to the first semiconductor chip CH1 and the bridge pad 132 to be connected to the second semiconductor chip CH2.

A second core laminated structure 140 may be disposed on the second surface 110F2 of the core substrate 110. The second core laminated structure 140 may include a plurality of second core insulating layers 142 and a plurality of second core wiring layers 144. In some embodiments, the plurality of second core insulating layers 142 may include at least one of ABF, BCB, PID, PSPI, solder resist, EMC, FR-4, and BT.

The plurality of second core wiring layers 144 may be disposed between each of the plurality of second core insulating layers 142 and covered by the plurality of second core insulating layers 142. The plurality of second core wiring layers 144 may form lower conductive paths electrically connected to the core substrate 110 and each include a via portion 144V and a wiring portion 144 W. A respective wiring portion 144 W may extend in the horizontal direction between a corresponding pair of the plurality of second core insulating layers 142 and may be disposed on a corresponding one of a plurality of vertical levels. The via portion 144V may be disposed inside a via hole penetrating the plurality of second core insulating layers 142 and may connect the wiring portions 144 W to each other between the wiring portions 144 W disposed at different vertical levels. In some example embodiments, the via portion 144V and the wiring portion 144 W may include at least one of copper (Cu), nickel (Ni), chromium (Cr), titanium (Ti), gold (Au), platinum (Pt), silver (Ag), or tungsten (W).

In some example embodiments, the plurality of second core insulating layers 142 may have a third coefficient of thermal expansion, and the third coefficient of thermal expansion may be less than the first coefficient of thermal expansion. For example, in some example embodiments, the third coefficient of thermal expansion may be in a range from about 3 ppm/° C. to about 20 ppm/° C. In other example embodiments, the third coefficient of thermal expansion may be in a range from about 1 ppm/° C. to about 40 ppm/° C.

In some example embodiments, a difference between the first coefficient of thermal expansion of the first core insulating layer 122 and the third coefficient of thermal expansion of the second core insulating layer 142 may be 5 ppm/° C. or less or 10 ppm/° C. or less. In some example embodiments, the third coefficient of thermal expansion of the second core insulating layer 142 may be less than the first coefficient of thermal expansion of the first core insulating layer 122 and greater than the second coefficient of thermal expansion of the bridge substrate 131. In other some embodiments, the third coefficient of thermal expansion of the second core insulating layer 142 may be less than the first coefficient of thermal expansion of the first core insulating layer 122 and less than the second coefficient of thermal expansion of the bridge substrate 131.

A solder resist layer 146 may be disposed on a lower surface of the second core laminated structure 140. The solder resist layer 146 may include an opening, and the opening of the solder resist layer 146 may expose the lowermost wiring portions 144 W without covering them. Connection bumps such as solder balls may further be disposed on the lowermost wiring portions 144 W exposed by the opening of the solder resist layer 146.

The redistribution structure 150 may be disposed on the first core laminated structure 120. The redistribution structure 150 may include a redistribution insulating layer 152 and a redistribution conductive layer 154. The redistribution structure 150 may be disposed on the first core laminated structure 120 to cover the first chip mounting space 120R. In some example embodiments, an underfill member 156 may further be disposed to surround side and bottom surfaces of the bridge chip 130 in the first chip mounting space 120R, and the underfill member 156 may be connected to the redistribution insulating layer 152.

Because a thermal expansion coefficient of silicon is less than that of an insulating material, a package substrate including a bridge chip including silicon may have an asymmetric structure in terms of a thermal expansion coefficient. In this case, in a process of mounting a semiconductor chip on a package substrate, for example, a reflow process or a thermal compression process, warpage may occur on the package substrate due to a local difference in coefficient of thermal expansion.

However, according to the package substrate 100 according to some example embodiments, the third coefficient of thermal expansion of the second core insulating layer 142 may be less than the first coefficient of thermal expansion of the first core insulating layer 122, and thus an imbalance or asymmetry in the coefficient of thermal expansion between an upper portion of the package substrate 100 disposed at a vertical level higher than the core substrate 110 and a lower side of the package substrate 100 disposed at a vertical level lower than the core substrate 110 may be reduced or minimized. Accordingly, even when high-temperature processes for mounting a semiconductor chip on the package substrate 100 are performed, the occurrence of warpage may be reduced or prevented.

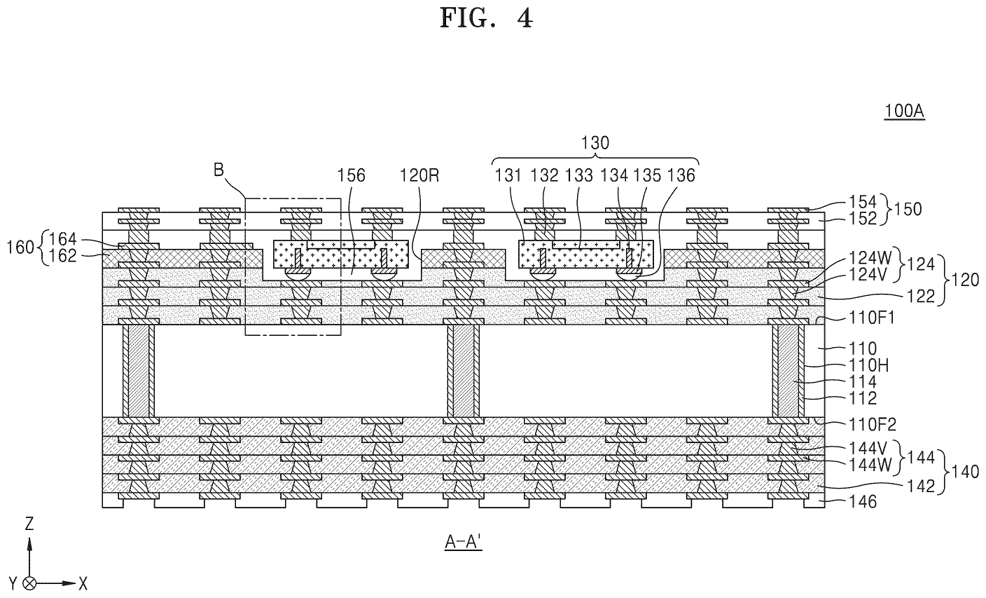

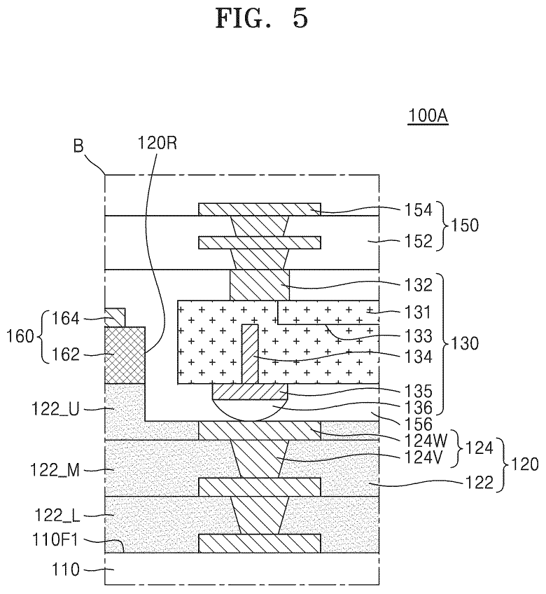

FIG. 4 is a cross-sectional view illustrating a package substrate 100A according to an example embodiment. FIG. 5 is an enlarged view of part B of FIG. 4.

Referring to FIGS. 4 and 5, the package substrate 100A may further include a first middle core laminated structure 160. The first middle core laminated structure 160 may be disposed at a higher vertical level than the first core laminated structure 120. For example, a vertical distance to the first middle core laminated structure 160 from the first surface 110F1 of the core substrate 110 may be greater than a vertical distance to the first core laminated structure 120 from the first surface 110F1 of the core substrate 110. The first core laminated structure 120 is directly disposed on the first surface 110F1 of the core substrate 110, and the first core laminated structure 120 may be interposed between the first middle core laminated structure 160 and the first surface 110F1 of the core substrate 110.

As shown in FIG. 5, at least a portion of the first chip mounting space 120R may be defined in the first middle core laminated structure 160. For example, the sidewall of the first middle core laminated structure 160 may define an upper portion of the first chip mounting space 120R, and a sidewall of the first core laminated structure 120 may define a lower side and a bottom of the first chip mounting space 120R. In this case, the first chip mounting space 120R may be formed by removing a portion of the first middle core laminated structure 160 and a portion of the first core laminated structure 120. However, unlike that shown in FIG. 5, sidewalls and bottom of the first middle core laminated structure 160 may define the first chip mounting space 120R, and the first core stacked laminated structure 120 may not be exposed to the first chip mounting space 120R.

The first middle core laminated structure 160 may include a third core insulating layer 162 and a third core wiring layer 164. The third core insulating layer 162 may have a fourth coefficient of thermal expansion, and the fourth coefficient of thermal expansion may be greater than the first coefficient of thermal expansion of the first core insulating layer 122 and/or the third coefficient of thermal expansion of the second core insulating layer 142.

In some example embodiments, the fourth coefficient of thermal expansion of the third core insulating layer 162 may be greater than the first coefficient of thermal expansion of the first core insulating layer 122, and the first coefficient of thermal expansion of the first core insulating layer 122 may be greater than the third coefficient of thermal expansion of the second core insulating layer 142. In some example embodiments, the fourth coefficient of thermal expansion of the third core insulating layer 162 may be greater than the first coefficient of thermal expansion of the first core insulating layer 122, and the first coefficient of thermal expansion of the first core insulating layer 122 may be substantially the same as the third coefficient of thermal expansion of the second core insulating layer 142.

In some example embodiments, the first coefficient of thermal expansion of the first core insulating layer 122 and the third coefficient of thermal expansion of the second core insulating layer 142 may have a range from about 3 ppm/° C. to about 20 ppm/° C. In some example embodiments, the first coefficient of thermal expansion of the first core insulating layer 122 and the third coefficient of thermal expansion of the second core insulating layer 142 may have a range from about 1 ppm/° C. to about 40 ppm/° C. In some example embodiments, the fourth coefficient of thermal expansion of the third core insulating layer 162 may have a range from about 5 ppm/° C. to about 30 ppm/° C. In some example embodiments, the fourth coefficient of thermal expansion of the third core insulating layer 162 may be in a range from about 1 ppm/° C. to about 50 ppm/° C.

Because a thermal expansion coefficient of silicon is less than that of an insulating material, a package substrate including a bridge chip including silicon may have an asymmetric structure in terms of a thermal expansion coefficient. In this case, in a process of mounting a semiconductor chip on the package substrate, for example, a reflow process or a thermal compression process, warpage may occur on the package substrate due to a local difference in thermal expansion coefficient.

However, in the package substrate 100A according to some example embodiments, the fourth coefficient of thermal expansion of the third core insulating layer 162 may be greater than the first coefficient of thermal expansion of the first core insulating layer 122 and/or the third coefficient of thermal expansion of the second core insulating layer 142, and accordingly an imbalance or asymmetry in the coefficient of thermal expansion between an upper portion of the package substrate 100A disposed at a vertical level higher than the core substrate 110 and a lower side of the package substrate 100A disposed at a vertical level lower than the core substrate 110, may be reduced or minimized. Accordingly, even when high-temperature processes for mounting a semiconductor chip on the package substrate 100A are performed, the occurrence of warpage may be reduced or prevented.

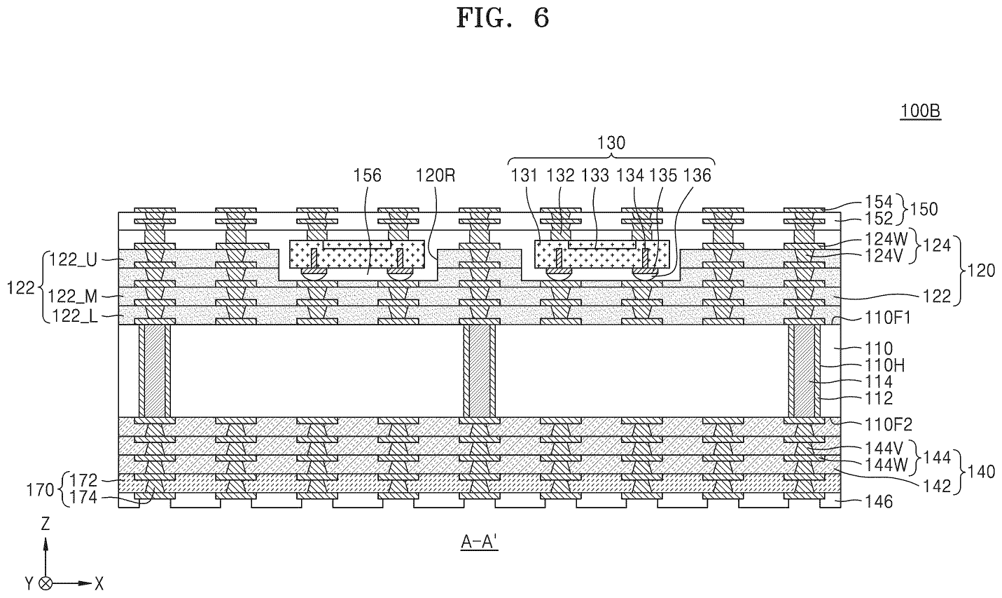

FIG. 6 is a cross-sectional view illustrating a package substrate 100B according to an example embodiment.

Referring to FIG. 6, the package substrate 100B may further include a second middle core laminated structure 170. The second middle core laminated structure 170 may be disposed at a lower vertical level than the second core laminated structure 140. For example, a vertical distance from the second surface 110F2 of the core substrate 110 to the second middle core laminated structure 170 may be greater than a vertical distance from the second surface 110F2 of the core substrate 110 to the second core laminated structure 140. The second core laminate structure 140 is directly disposed on the second surface 110F2 of the core substrate 110, and the second core laminated structure 140 may be interposed between the second middle core laminated structure 170 and the second surface 110F2 of the core substrate 110. The second middle core laminated structure 170 may cover the entire bottom surface of the second core laminated structure 140.

The second middle core laminated structure 170 may include a fourth core insulating layer 172 and a fourth core wiring layer 174. The fourth core insulating layer 172 may have a fifth coefficient of thermal expansion, and the fifth coefficient of thermal expansion may be less than the first coefficient of thermal expansion of the first core insulating layer 122 and/or the third coefficient of thermal expansion of the second core insulating layer 142.

In some example embodiments, the fifth coefficient of thermal expansion of the fourth core insulating layer 172 may be less than the first coefficient of thermal expansion of the first core insulating layer 122, and the first coefficient of thermal expansion of the first core insulating layer 122 may be greater than the third coefficient of thermal expansion of the second core insulating layer 142. In some example embodiments, the fifth coefficient of thermal expansion of the fourth core insulating layer 172 may be less than the first coefficient of thermal expansion of the first core insulating layer 122, and the first coefficient of thermal expansion of the first core insulating layer 122 may be substantially the same as the third coefficient of thermal expansion of the second core insulating layer 142.

In some example embodiments, the first coefficient of thermal expansion of the first core insulating layer 122 and the third coefficient of thermal expansion of the second core insulating layer 142 may have a range from about 5 ppm/° C. to about 30 ppm/° C. In some example embodiments, the first coefficient of thermal expansion of the first core insulating layer 122 and the third coefficient of thermal expansion of the second core insulating layer 142 may have a range from about 1 ppm/° C. to about 50 ppm/° C. In some example embodiments, the fourth coefficient of thermal expansion of the third core insulating layer 162 may have a range from about 3 ppm/° C. to about 20 ppm/° C. In some example embodiments, the fourth coefficient of thermal expansion of the third core insulating layer 162 may have a range from about 1 ppm/° C. to about 40 ppm/° C.

In the package substrate 100B according to some example embodiments, the fifth coefficient of thermal expansion of the fourth core insulating layer 172 may be less than the first coefficient of thermal expansion of the first core insulating layer 122 and/or the third coefficient of thermal expansion of the second core insulating layer 142, and thus an imbalance or asymmetry in the coefficient of thermal expansion between an upper portion of the package substrate 100B disposed at a vertical level higher than the core substrate 110 and a lower side of the package substrate 100B disposed at a vertical level lower than the core substrate 110 may be reduced or minimized. Accordingly, even when high-temperature processes for mounting a semiconductor chip on the package substrate 100B are performed, the occurrence of warpage can be reduced or prevented.

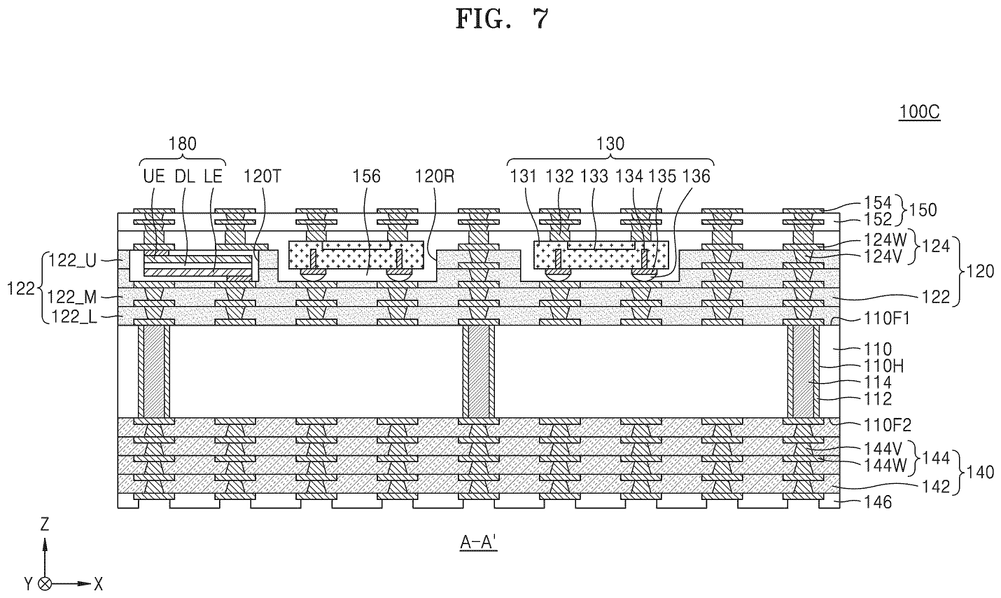

FIG. 7 is a cross-sectional view illustrating a package substrate 100C according to an example embodiment.

Referring to FIG. 7, the first core-laminated structure 120 may further include a second chip mounting space 120T spaced apart from the first chip mounting space 120R. In some example embodiments, the second chip mounting space 120T may be horizontally spaced apart from each other at the same vertical level as the first chip mounting space 120R. For example, the second chip mounting space 120T may be disposed on an upper portion of the first core laminated structure 120. In some example embodiments, the second chip mounting space 120T may be disposed at a lower vertical level than the first chip mounting space 120R, and in this case, a distance between the second chip mounting space 120T and the first surface 110F1 of the core substrate 110 may be less than a distance between the first chip mounting space 120R and the first surface 110F1 of the core substrate 110.

In some example embodiments, a capacitor 180 may be disposed in the second chip mounting space 120T. The capacitor 180 may include a lower electrode layer LE, a dielectric layer DL, and an upper electrode layer UE, and may include a thin film decoupling capacitor having a metal-insulator-metal (MIM) structure. As shown in FIG. 7, the capacitor 180 may include a planar capacitor but in some example embodiments, the capacitor 180 may include a cylindrical capacitor or a multilayer-stacked capacitor.

The lower electrode layer LE may include at least one of copper (Cu), nickel (Ni), iridium (Ir), molybdenum (Mo), gold (Au), platinum (Pt), titanium (Ti), tantalum (Ta), chromium (Cr), tungsten (W), aluminum (Al), or an alloy thereof. The dielectric layer DL may include a high-k dielectric material. The high-k dielectric material may refer to a material that has a dielectric constant greater than that of silicon oxide. In some example embodiments, the dielectric layer DL may include a material having a dielectric constant of about 5 or more or about 10 or more. For example, the dielectric layer DL may include hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate, or combinations thereof, but is not limited thereto. The upper electrode layer UE may include at least one of copper (Cu), nickel (Ni), iridium (Ir), molybdenum (Mo), gold (Au), platinum (Pt), titanium (Ti), tantalum (Ta), chromium (Cr), tungsten (W), aluminum (Al), or an alloy thereof.

In some example embodiments, passive devices, such as inductors, resistors, and capacitors may further be disposed in the second chip mounting space 120T.

A package substrate in which a passive device, such as a capacitor and/or a bridge chip is embedded on an upper portion of the package substrate may have an asymmetric structure in terms of a thermal expansion coefficient. In this case, in a process of mounting a semiconductor chip on the package substrate, for example, a reflow process or a thermal compression process, warpage may occur on the package substrate due to a local difference in thermal expansion coefficient.

However, in the package substrate 100C according to some example embodiments, the third coefficient of thermal expansion of the second core insulating layer 142 may less than the first coefficient of thermal expansion of the first core insulating layer 122. Accordingly, an imbalance or asymmetry in the coefficient of thermal expansion between an upper portion of the package substrate 100C disposed at a vertical level higher than the core substrate 110 and a lower portion of the package substrate 100C disposed at a vertical level lower than the core substrate 110 may be reduced or minimized. Accordingly, the occurrence of warpage may be reduced or prevented even when high-temperature processes for mounting semiconductor chips on the package substrate 100C are performed.

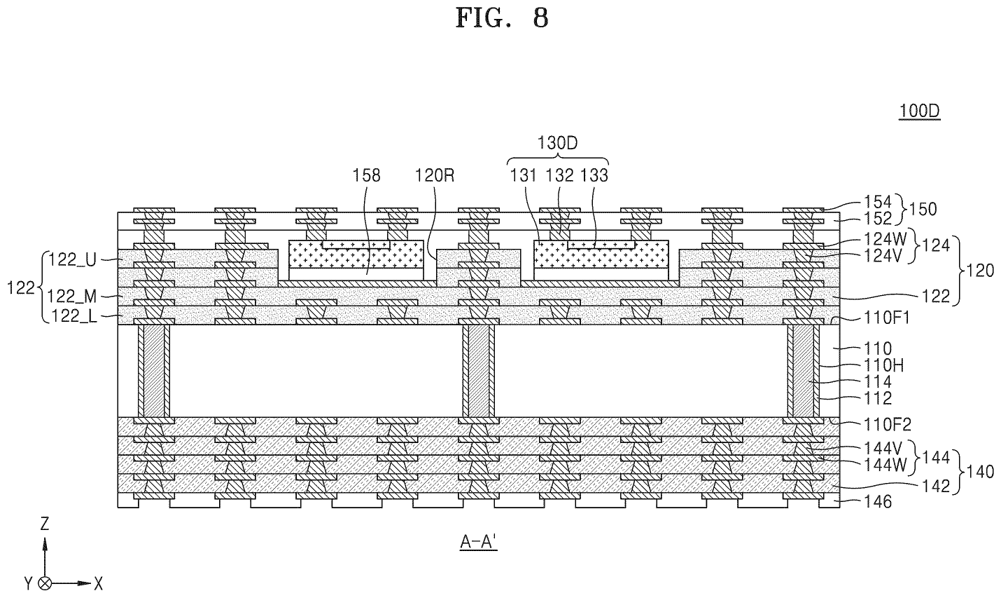

FIG. 8 is a cross-sectional view illustrating a package substrate 100D according to an example embodiment.

Referring to FIG. 8, the package substrate 100D may include a bridge chip 130D disposed in the first chip mounting space 120R, and the bridge chip 130D may be different from the bridge chip 130 described with reference to FIGS. 1 to 7 in that the bridge chip 130D does not include a bridge through-via. A bottom surface of the bridge chip 130D may be attached to the first core wiring layer 124 through an adhesive layer 158. In some example embodiments, the adhesive layer 158 may include an adhesive material, such as a die attach film (DAF), adhesive paste, or epoxy resin.

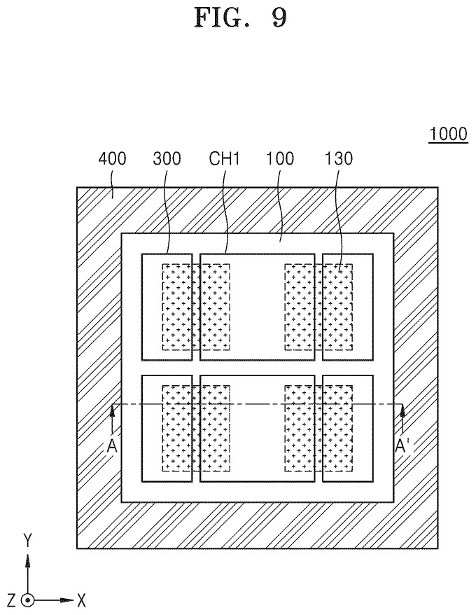

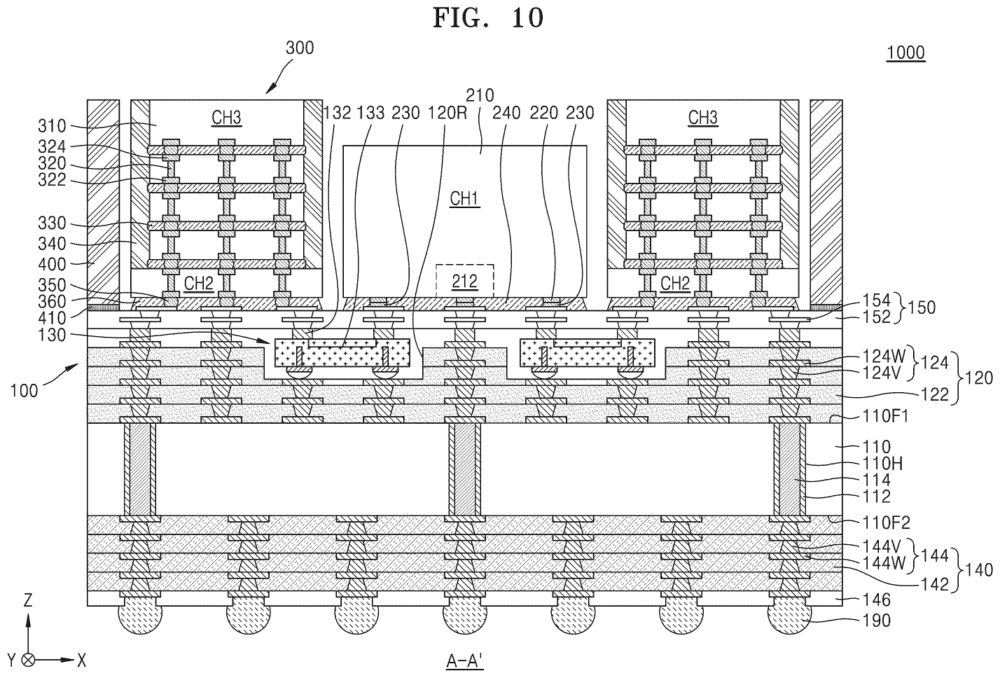

FIG. 9 is a plan layout illustrating a semiconductor package 1000 according to an example embodiment, and FIG. 10 is a cross-sectional view taken along line A-A′ of FIG. 9.

Referring to FIGS. 9 and 10, the semiconductor package 1000 includes a package substrate 100 and a first semiconductor chips CH1 and at least one laminated structure 300 mounted on the package substrate 100. The at least one laminated structure 300 and the plurality of first semiconductor chips CH1 may be spaced apart from each other in the horizontal direction and attached to the package substrate 100.

Although the semiconductor package 1000 is illustrated as including four laminated structures 300 attached to the package substrate 100 in FIG. 9, example embodiments are not limited thereto. For example, the semiconductor package 1000 may include one, two, four, six, eight, or more laminated structures 300. The laminated structure 300 may be referred to as a memory stack.

At least some of the first semiconductor chips CH1 may be logic semiconductor chips. At least some of the first semiconductor chips CH1 may include one of, for example, a central processing unit (CPU) chip, a graphic processing unit (GPU) chip, an application processor (AP) chip, an application specific integrated circuit (ASIC), or other processing chips.

The first semiconductor chip CH1 may include a substrate 210 having an active surface and an inactive surface opposite to each other, a semiconductor device 212 formed on the active surface of the substrate 210, and a plurality of front connection pads 220 disposed on the active surface of the substrate 210. The first semiconductor chip CH1 may be disposed so that the active surface of the substrate 210 faces the package substrate 100. The first semiconductor chip CH1 may be electrically connected to the package substrate 100 through the front connection pads 220 and connection bumps 230 provided on the active surface. An underfill member 240 may be disposed between a lower surface of the first semiconductor chip CH1 and the package substrate 100 to surround the connection bumps 230.

The substrate 210 may include, for example, a semiconductor material such as silicon (Si) or germanium (Ge). In some example embodiments, the substrate 210 may include a compound semiconductor material, such as silicon carbide (SiC), gallium arsenide (GaAs), indium arsenide (InAs), and indium phosphide (InP). The substrate 210 may include a conductive region, for example, a well doped with an impurity. The substrate 210 may have various device isolation structures, such as a shallow trench isolation (STI) structure.

A semiconductor device 212 including a plurality of individual devices of various types may be formed on the active surface of the substrate 210. The plurality of individual devices may include various microelectronic devices, for example, a metal-oxide-semiconductor field effect transistor (MOSFET), such as a complementary metal-insulator-semiconductor transistor (CMOS transistor), a system large scale integration (LSI), active elements, passive elements, etc. The plurality of individual devices may be electrically connected to the conductive region of the substrate 210. The semiconductor element 212 may further include a conductive wiring or a conductive plug that electrically connects at least two of the plurality of individual devices or the plurality of individual devices to the conductive region of the substrate 210. In addition, each of the plurality of individual devices may be electrically separated from other neighboring individual devices by an insulating layer.

The at least one laminated structure 300 may include a second semiconductor chip CH2 and a plurality of third semiconductor chips CH3. In some example embodiments, one laminated structure 300 may include a multiple of four third semiconductor chips CH3. The plurality of third semiconductor chips CH3 may be sequentially laminated on the second semiconductor chip CH2 in a vertical direction. Each of the second semiconductor chip CH2 and the plurality of third semiconductor chips CH3 may be sequentially laminated with active surfaces facing downward, that is, toward the package substrate 100.

The second semiconductor chip CH2 and the plurality of third semiconductor chips CH3 may include a dynamic random access memory (DRAM), a static random access memory (SRAM), a flash memory, an electrically erasable and programmable read-only memory (EEPROM), a phase-change random access memory (PRAM), a magnetic random access memory (MRAM), or a resistive random access memory (RRAM).

In some example embodiments, the second semiconductor chip CH2 may not include a memory cell. The second semiconductor chip CH2 may include a test logic circuit, such as a serial-parallel conversion circuit, a design for test (DFT), a joint test action group (JTAG), or a memory built-in self-test (MBIST) and a signal interface circuit, such as PHY. The plurality of third semiconductor chips CH3 may include memory cells. For example, the second semiconductor chip CH2 may be a buffer chip for controlling the plurality of third semiconductor chips CH3.

In some example embodiments, the second semiconductor chip CH2 may be a buffer chip for controlling a High-Bandwidth Memory (HBM) DRAM, and the plurality of third semiconductor chips CH3 may be memory cell chips having a cell of the HBM DRAM that is controlled by the second semiconductor chip CH2. The second semiconductor chip CH2 may be referred to as a buffer chip or a master chip, and the plurality of third semiconductor chips CH3 may be referred to as slave chips or memory cell chips. The laminated structure 300 including the second semiconductor chip CH2 and the plurality of third semiconductor chips CH3 sequentially laminated on the second semiconductor chip CH2 may be referred to as an HBM DRAM device.

Each of the second semiconductor chip CH2 and the plurality of third semiconductor chips CH3 may include a substrate 310, a plurality of through electrodes 320, a plurality of first front connection pads 322, and a plurality of first rear surface connection pads 324. The substrate 310 may include silicon (Si). In some example embodiments, the substrate 310 may include a semiconductor element, such as germanium (Ge) or a compound semiconductor, such as silicon carbide (SiC), gallium arsenide (GaAs), indium arsenide (InAs), and indium phosphide (InP). The substrate 310 may have an active surface and an inactive surface opposite to the active surface. The substrate 310 may include a plurality of individual devices of various types on the active surface. The plurality of individual devices may include various microelectronics devices, for example, a MOSFET such as, a CMOS transistor, an LSI, an image sensor such as a CMOS image sensor, a micro-electro-mechanical system (MEMS), an active element, a passive element, and the like.

The plurality of through electrodes 320 may vertically penetrate at least a portion of the substrate 310 to electrically connect the plurality of the first front connection pads 322 and the plurality of first rear surface connection pads 324 to each other. An insulating adhesive layer 330 may be interposed between the second semiconductor chip CH2 and a bottommost one of the plurality of third semiconductor chips CH3 and between respective pairs of the plurality of third semiconductor chips CH3. The insulating adhesive layer 330 is attached to a lower surface of each of the plurality of third semiconductor chips CH3 to attach each of the plurality of third semiconductor chips CH3 to a lower structure, for example, the second semiconductor chip CH2 or another third semiconductor chip positioned below the plurality of third semiconductor chips CH3. The insulating adhesive layer 330 may include a non-conductive film (NCF), a non-conductive paste (NCP), an insulating polymer, or an epoxy resin. The insulating adhesive layer 330 may cover chip connection terminals 350 and fill between each of the second semiconductor chip CH2 or the plurality of third semiconductor chips CH3.

The laminated structure 300 may further include a chip molding layer 340 covering the plurality of third semiconductor chips CH3 on an upper surface of the second semiconductor chip CH2. The chip molding layer 340 may cover the upper surface of the second semiconductor chip CH2 and side surfaces of the plurality of third semiconductor chips CH3. In some example embodiments, the chip molding layer 340 covers the side surfaces of the plurality of third semiconductor chips CH3, but does not cover an upper surface of the third semiconductor chip CH3 positioned at the top, that is, an inactive surface of the third semiconductor chip CH3 positioned at the top may be exposed without being covered. The chip molding layer 340 may include, for example, EMC.

The laminated structure 300 may be electrically connected to the package substrate 100 through the first front connection pads 322 provided on the active surface of the second semiconductor chip CH2 and the chip connection terminals 350. An underfill member 360 may be disposed between the lower surface of the laminated structure 300 and the package substrate 100 to surround the chip connection terminals 350.

As described with reference to FIGS. 9 and 10, the package substrate 100 may include the first core laminated structure 120 and the bridge chip 130 disposed on the first surface 110F1 of the core substrate 110, and the second core laminated structure 140 disposed on the second surface 110F2 of the core substrate 110. The redistribution structure 150 may be disposed on the first core laminated structure 120 and the bridge chip 130.

The bridge chip 130 may be disposed to vertically overlap both a portion of the first semiconductor chip CH1 and a portion of the laminated structure 300 adjacent the first semiconductor chip CH1.

The plurality of first bridge pads 132 included in the bridge chip 130 may overlap in a vertical direction with some of the plurality of front connection pads 220 included in the first semiconductor chip CH1. Some of the plurality of bridge pads 132 included in the bridge chip 130 may be connected to first ends of the plurality of bridge wirings 133, and some other of the plurality of bridge pads 132 may be connected to second ends of the plurality of bridge wirings 133. For example, the bridge pads 132 connected to the first ends of the bridge wirings 133 may contact and be connected to some of the plurality of front connection pads 220 included in the first semiconductor chip CH1, and the bridge pads 132 connected to the second ends of the bridge wirings 133 may be connected to some of the plurality of first front connection pads 322 included in the laminated structure 300.

As shown in FIG. 10, the redistribution structure 150 is interposed between the bridge pads 132 and the front connection pad 220, and thus the bridge pads 132 and the front connection pads 220 are electrically connected to each other through the redistribution conductive layer 154. In addition, the redistribution structure 150 is interposed between the bridge pads 132 and the first front connection pads 322, and thus the bridge pads 132 and the first front connection pads 322 may be electrically connected to each other through the redistribution conductive layer 154. In some example embodiments, the redistribution structure 150 may be omitted, and in this case, the bridge pads 132 and the front connection pads 220 may be directly connected, and the bridge pads 132 and the first front connection pads 322 may be directly connected.

The semiconductor package 1000 may further include a stiffener structure 400 attached to the package substrate 100. The stiffener structure 400 may be attached to the package substrate 100 with a stiffener thermal interface material layer 410 therebetween. In some example embodiments, the stiffener structure 400 may be attached on the package substrate 100 to be spaced apart from the laminated structure 300 and the first semiconductor chip CH1. The stiffener structure 400 may extend along an edge of the package substrate 100 in a plan view, that is, in a top-view, and may surround the laminated structure 300 and the first semiconductor chip CH1.

The stiffener structure 400 may include a metal. For example, the stiffener structure 400 may include at least one of copper, nickel, or stainless steel. The stiffener thermal interface material layer 410 may include an insulating material or a material capable of maintaining electrical insulation by including an insulating material. The stiffener thermal interface material layer 410 may include, for example, an epoxy resin. The stiffener thermal interface material layer 410 may include, for example, a mineral oil, grease, a gap filler putty, a phase change gel, a phase change material pad, or particle filled epoxy. For example, the stiffener structure 400 may have a vertical height in a range from about 500 μm to about 800 μm.

In some example embodiments, the semiconductor package 1000 may further include a package molding layer (not shown) surrounding at least one laminated structure 300 and the first semiconductor chip CH1 on the package substrate 100. The package molding layer may include, for example, EMC. Connection bumps 190, such as solder balls may further be disposed on a lower surface of the package substrate 100.

Although FIGS. 9 and 10 show that the semiconductor package 1000 includes the package substrate 100 described with reference to FIGS. 1 to 3, in some example embodiments, the semiconductor package 1000 may include the package substrates 100A, 100B, 100C, and 100D described with reference to FIGS. 4 to 8.

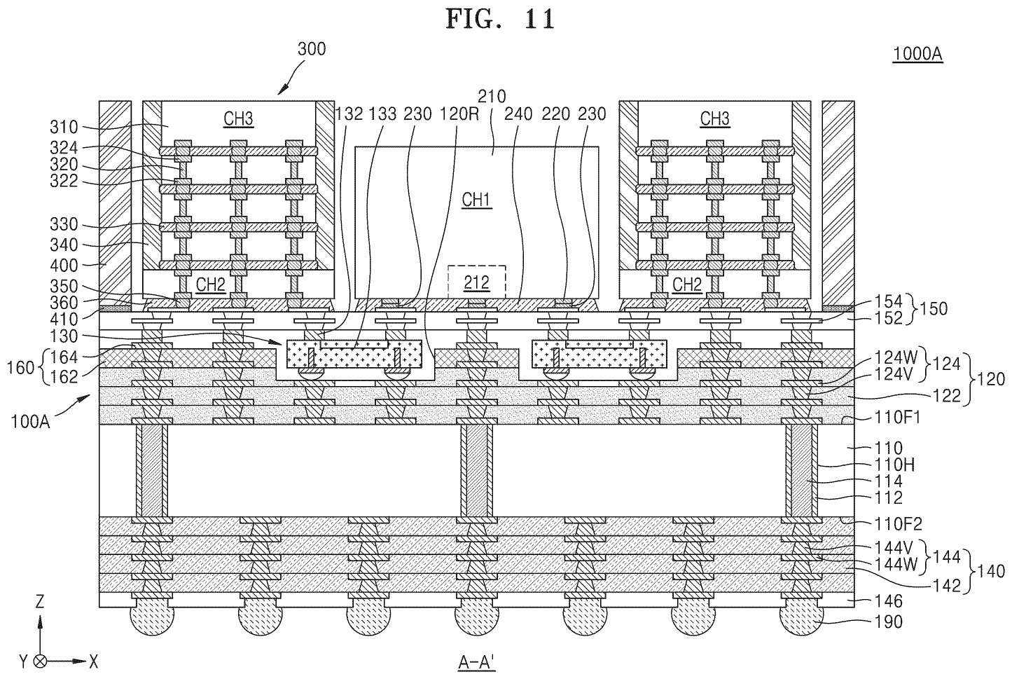

FIG. 11 is a cross-sectional view illustrating a semiconductor package 1000A according to an example embodiment.

Referring to FIG. 11, the semiconductor package 1000A includes a package substrate 100A and a first semiconductor chip CH1 and at least one laminated structure 300 mounted on the package substrate 100A. The package substrate 100A may further include a first middle core laminated structure 160 disposed at a higher vertical level than the first core laminated structure 120. At least a portion of the first chip mounting space 120R may be defined in the first middle core laminated structure 160, and, in a plan view, an upper portion of the bridge chip 130 may be surrounded by the first middle core laminated structure 160.

The first middle core laminated structure 160 may include a third core insulating layer 162 and a third core wiring layer 164. The third core insulating layer 162 may have a fourth coefficient of thermal expansion, and the fourth coefficient of thermal expansion may be greater than the coefficient of thermal expansion of the first coefficient of thermal expansion of the first core insulating layer 122 and/or the third coefficient of thermal expansion of the second core insulating layer 142.

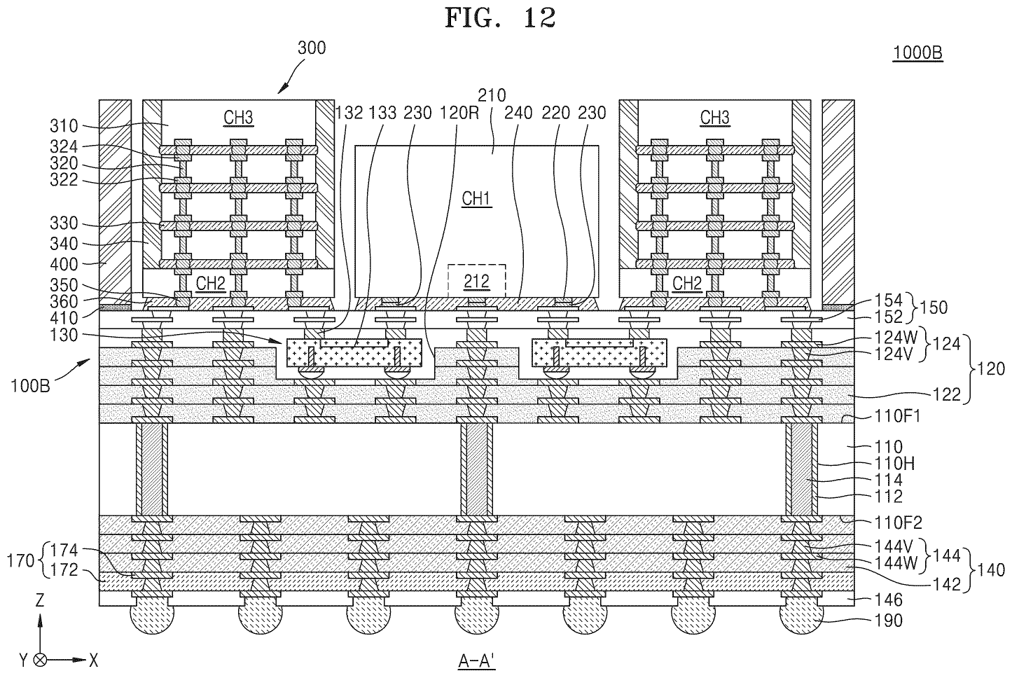

FIG. 12 is a cross-sectional view illustrating a semiconductor package 1000B according to an example embodiment.

Referring to FIG. 12, the semiconductor package 1000B may include a package substrate 100B, and a first semiconductor chip CH1 mounted and at least one laminated structure 300 on the package substrate 100B. The package substrate 100B may further include a second middle core laminated structure 170 disposed at a vertical level lower than the second core stack structure 140.

The second middle core laminated structure 170 may include a fourth core insulating layer 172 and a fourth core wiring layer 174. The fourth core insulating layer 172 may have a fifth coefficient of thermal expansion, and the fifth coefficient of thermal expansion may be less than the first coefficient of thermal expansion of the first core insulating layer 122 and/or the third coefficient of thermal expansion of the second core insulating layer 142.

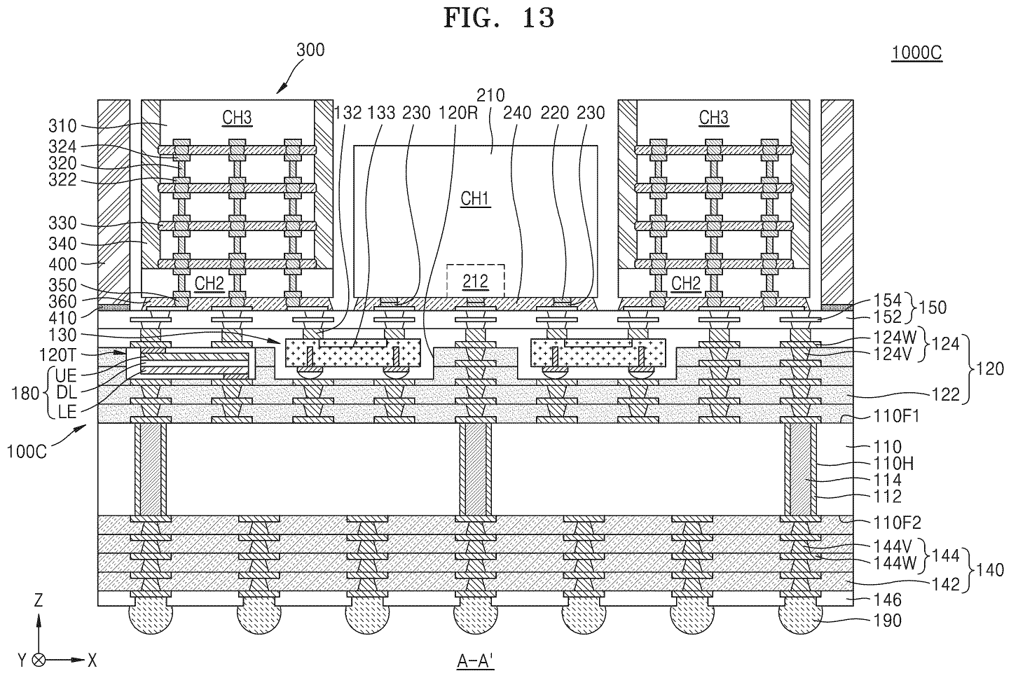

FIG. 13 is a cross-sectional view illustrating a semiconductor package 1000C according to an example embodiment.

Referring to FIG. 13, the semiconductor package 1000C includes a package substrate 100C, and a first semiconductor chip CH1 and at least one stack structure 300 mounted on the package substrate 100C. The first core stacked structure 120 may further include a second chip mounting space 120T disposed on the first core laminated structure 120 and spaced apart from the first chip mounting space 120R. In some example embodiments, a capacitor 180 may be disposed in the second chip mounting space 120T. The capacitor 180 may include a lower electrode layer LE, a dielectric layer DL, and an upper electrode layer UE, and may be a planar thin-film decoupling capacitor having a metal-insulator-metal (MIM) structure. In some example embodiments, passive elements, such as inductors, resistors, and capacitors may further be disposed in the second chip mounting space 120T.

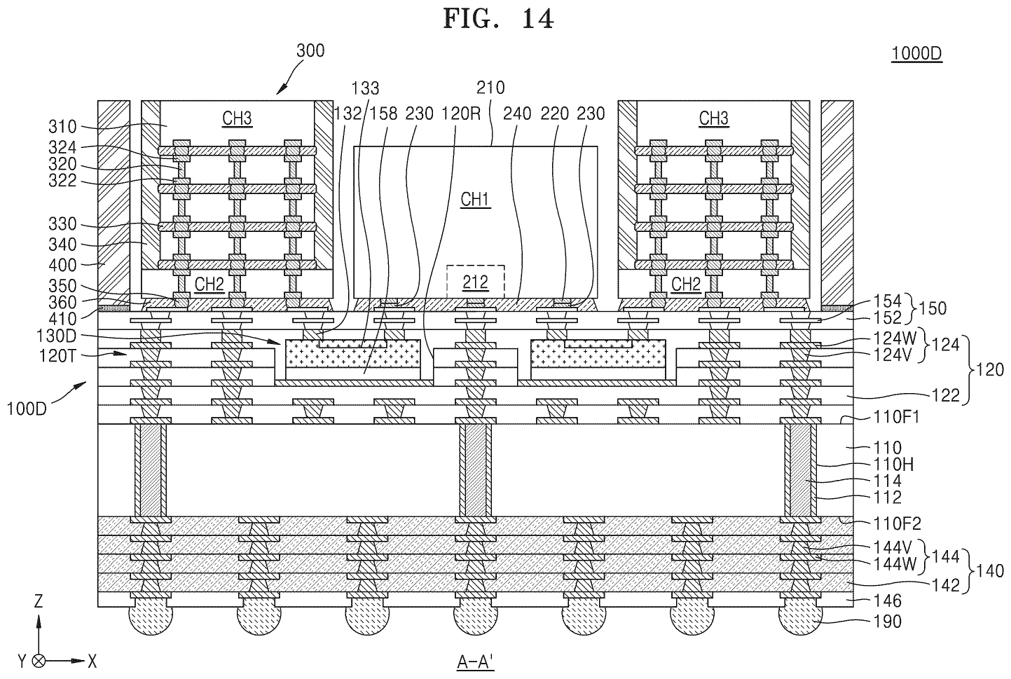

FIG. 14 is a cross-sectional view illustrating a semiconductor package 1000D according to an example embodiment.

Referring to FIG. 14, the semiconductor package 1000D includes a package substrate 100D, and a first semiconductor chip CH1 and at least one laminated structure 300 mounted on the package substrate 100D. The package substrate 100D may include a bridge chip 130D disposed in the first chip mounting space 120R, and the bridge chip 130D does not include a through-bridge via. A bottom surface of the bridge chip 130D may be attached to the first core wiring layer 124 through an adhesive layer 158.

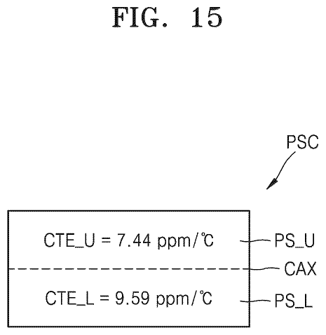

FIG. 15 is a schematic diagram illustrating warpage simulation of a package substrate PSC according to a Comparative Example.

Referring to FIG. 15, in the package substrate PSC according to the Comparative Example, a central axis CAX as a reference, a substrate upper portion PS_U and a substrate lower portion PS_L have an asymmetrical structure in terms of a thermal expansion coefficient. For example, the package substrate PSC according to the Comparative Example has a structure similar to that of the package substrate 100 described with reference to FIG. 2, but it is different from the package substrate 100 described with reference to FIG. 2 in that the first coefficient of thermal expansion of the first core insulating layer 122 of the first core laminated structure 120 is the same as the second coefficient of thermal expansion of the second core insulating layer 142 of the second core laminated structure 140. A total thermal expansion coefficient was calculated through simulation for each of the substrate upper portion PS_U and the substrate lower portion PS_L based on the central axis CAX using the package substrate PSC according to the structure according to the Comparative Example.

The substrate upper portion PS_U of the package substrate PSC according to the Comparative Example has a first total coefficient of thermal expansion CTE_U, and the first total coefficient of thermal expansion CTE_U has 7.44 ppm/° C. The substrate lower portion PS_L of the package substrate PSC according to the Comparative Example has a second total coefficient of thermal expansion CTE_L, and the second total coefficient of thermal expansion CTE_L has 9.59 ppm/° C. The first total coefficient of thermal expansion CTE_U of the substrate upper portion PS_U may be less than the second total coefficient of thermal expansion CTE_L of the substrate lower portion PS_L by about 2.15 ppm/° C., which may be due to a relatively low coefficient of thermal expansion of the bridge chip including silicon disposed on the substrate upper portion PS_U of the package substrate PSC.

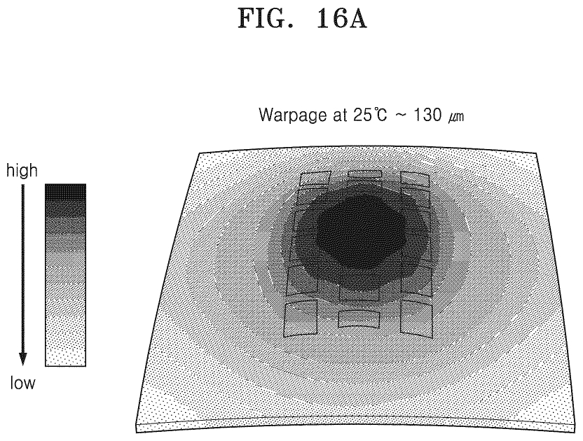

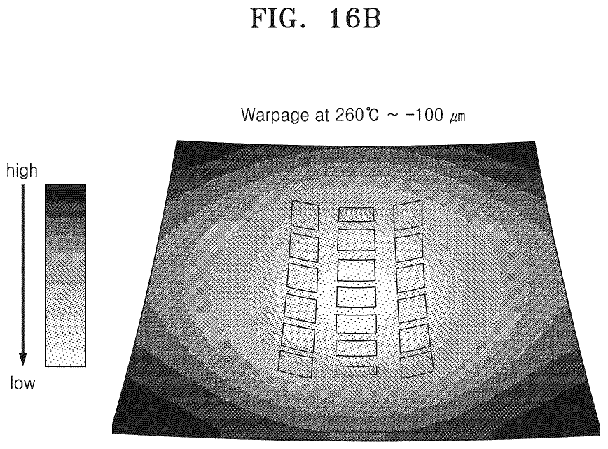

FIGS. 16A and 16B are warpage simulation mapping diagrams of a package substrate according to a Comparative Example.

Referring to FIG. 16A, the package substrate according to the Comparative Example shows warpage of about 130 μm at room temperature, for example, 25° C. The warpage having a positive value of 130 μm may mean that the central portion of the substrate protrudes convexly upward by 130 μm relative to edge portions of the substrate. That is, an upward bending force is applied to the central portion of the substrate, and thus, the central portion of the substrate is positioned at a higher vertical level than the edge portions of the substrate. This may be a result obtained because the first total coefficient of thermal expansion CTE_U of the substrate upper portion PS_U is less than the second total coefficient of thermal expansion CTE_L of the substrate lower portion PS_L in the package substrate according to the Comparative Example described with reference to FIG. 15.

Referring to FIG. 16B, the package substrate according to the Comparative Example showed warpage of about −100 μm at a high temperature, for example, 260° C. The warpage having a negative value of −100 μm may mean that the central portion of the substrate protrudes convexly downward (or concavely upward) by −100 μm relative to the edge portions of the substrate. That is, a downward bending force is applied to the central portion of the substrate, and thus, the central portion of the substrate is positioned at a lower vertical level than the edge portions of the substrate. This may be a result obtained because the first total coefficient of thermal expansion CTE_U of the substrate upper portion PS_U is less than the second total coefficient of thermal expansion CTE_L of the substrate lower portion PS_L in the package substrate according to the Comparative Example described with reference to FIG. 15.

As such, when the temperature of the package substrate changes from room temperature to a high temperature, the package substrate undergoes a rapid warpage change of about 230 μm (e.g., from 130 μm to −100 μm). This may cause a misalignment problem or the like in a process of mounting a laminated structure of one semiconductor chip or a plurality of semiconductor chips on a package substrate.

On the other hand, in the package substrates 100, 100A, 100B, 100C, and 100D according to the example embodiments described with reference to FIGS. 1 to 8 and the semiconductor packages 1000, 1000A, 1000B, 1000C, and 1000D described with reference to FIGS. 9 to 14, a difference between the coefficient of thermal expansion of an upper portion of the core substrate and the coefficient of thermal expansion of a lower portion of the core substrate may be reduced or minimized, and accordingly, the occurrence of warpage problem in a process for mounting a semiconductor chip on a package substrate is reduced or prevented.

While the inventive concepts have been particularly shown and described with reference to some example embodiments thereof, it will be understood that various changes in form and details may be made therein without departing from the spirit and scope of the following claims.

What is claimed is:

1. A package substrate comprising:
a core substrate including a first surface and a second surface opposite to the first surface;
a first core laminated structure on the first surface of the core substrate, including a plurality of first core insulating layers and a plurality of first cores wiring layers on the plurality of first core insulating layers, and including a first chip mounting space defined by the plurality of first core insulating layers;
a bridge chip within the first chip mounting space and including a bridge substrate and a bridge pad; and
a second core laminated structure on the second surface of the core substrate, and including a plurality of second core insulating layers and a plurality of second core wiring layers on the plurality of second core insulating layers,
wherein the plurality of first core insulating layers have a first coefficient of thermal expansion, and the plurality of second core insulating layers have a second coefficient of thermal expansion less than the first coefficient of thermal expansion.

2. The package substrate of claim 1, wherein a difference between the first coefficient of thermal expansion and the second coefficient of thermal expansion is 5 ppm/° C. or less.

3. The package substrate of claim 1, wherein each of the first core insulating layers and the second core insulating layers includes at least one of an Ajinomoto build-up film (ABF), benzocyclobutene (BCB), photo-imageable dielectric (PID), photosensitive polyimide (PSPI), solder resist, an epoxy molding compound (EMC), flame retardant 4 (FR-4), or bismaleimide triazine (BT).

4. The package substrate of claim 1, wherein
the plurality of first core insulating layers include,
a lowermost core insulating layer being closest to the first surface of the core substrate, from among the plurality of first core insulating layers,
an uppermost core insulating layer being farthest from the first surface of the core substrate, from among the plurality of first core insulating layers, and
at least one middle core insulating layer being between the lowermost core insulating layer and the uppermost core insulating layer, from among the plurality of first core insulating layers,
a side of the first chip mounting space is surrounded by the uppermost core insulating layer, and
the at least one middle core insulating layer is exposed at a bottom of the first chip mounting space.

5. The package substrate of claim 4, wherein
the bridge pad is on an upper surface of the bridge substrate, and
the bridge chip further includes,
a bridge lower pad on a lower surface of the bridge substrate,
a bridge lower connection member electrically connected to the bridge lower pad and the first core wiring layers, and
a bridge through-via passing through the bridge substrate to electrically connect the bridge lower pad and the bridge pad to each other.

6. The package substrate of claim 4, wherein
the first chip mounting space is on a level corresponding to an upper portion of the first core laminated structure, and
the bridge chip is apart from the core substrate in a first direction perpendicular to the first surface of the core substrate.

7. The package substrate of claim 1, further comprising:
a connection bump on a lower surface of the second core laminated structure and electrically connected to the plurality of second core wiring layers.

8. The package substrate of claim 1, wherein
the bridge substrate includes silicon,
the bridge chip has a third coefficient of thermal expansion, and
the third coefficient of thermal expansion is less than the first coefficient of thermal expansion.

9. The package substrate of claim 1, further comprising
a first middle core laminate structure on the first core laminated structure, the first core laminated structure between the first surface of the core substrate and the first middle core laminated structure, and the first middle core laminate structure including a plurality of third core insulating layers and a plurality of third core wiring layers on the plurality of third core insulating layers,
wherein the plurality of third core insulating layers have a fourth coefficient of thermal expansion, and
the fourth coefficient of thermal expansion is less than the first coefficient of thermal expansion.

10. The package substrate of claim 9, wherein
a bottom surface of the first middle core laminated structure is in contact with an upper surface of the first core laminated structure, and
the bottom surface of the first middle core laminated structure is spaced apart from the first surface of the core substrate in a first direction perpendicular to the first surface of the core substrate.

11. The package substrate of claim 1, further comprising
a second middle core laminated structure on a bottom surface of the second core laminated structure, the second core laminated structure between the second surface of the core substrate and the second middle core laminated structure, and the second middle core laminated structure including a plurality of fourth core insulating layers and a plurality of fourth core wiring layers on the plurality of fourth core insulating layers,
wherein the plurality of fourth core insulating layers have a fifth coefficient of thermal expansion, and
the fifth coefficient of thermal expansion is less than the second coefficient of thermal expansion.

12. The package substrate of claim 11, wherein
an upper surface of the second middle core laminated structure is in contact with the bottom surface of the second core laminated structure, and
the upper surface of the second middle core laminate structure is spaced apart from the second surface of the core substrate in a first direction perpendicular to the first surface of the core substrate.

13. A package substrate comprising:
a core substrate including a first surface and a second surface opposite to the first surface;
a first core laminated structure on the first surface of the core substrate, including a plurality of first core insulating layers including a first insulating material having a first coefficient of thermal expansion, and including a plurality of first core wiring layers forming an upper conductive path that is electrically connected to the core substrate;
a second core laminated structure on the second surface of the core substrate, including a plurality of second core insulating layers including a second insulating material having a second coefficient of thermal expansion less than the first coefficient of thermal expansion, and including a plurality of second core wiring layers forming a lower conductive path electrically connected to the core substrate; and
a bridge chip in a first chip mounting space defined in an upper portion of the first core laminated structure and including a bridge substrate and a bridge pad, the bridge pad electrically connected to the upper conductive path.

14. The package substrate of claim 13, wherein
the bridge pad is on an upper surface of the first core laminated structure.

15. The package substrate of claim 13, wherein
the bridge substrate includes silicon,
the bridge chip has a third coefficient of thermal expansion, and
the third coefficient of thermal expansion is less than the first coefficient of thermal expansion.

16. The package substrate of claim 13, wherein
the bridge chip further includes,
a bridge lower pad on a lower surface of the bridge substrate,
a bridge lower connection member electrically connected to the bridge lower pad and the first core wiring layers, and
a bridge through-via passing through the bridge substrate and electrically connecting the bridge lower pad to the bridge pad.

17. The package substrate of claim 13, further comprising
a first middle core laminated structure on the first core laminated structure, the first core laminated structure being between the first surface of the core substrate and the first middle core laminated structure, the first middle core laminated structure including a plurality of third core insulating layers and a plurality of third core wiring layers on the plurality of third core insulating layers,
wherein the plurality of third core insulating layers have a fourth coefficient of thermal expansion, and
the fourth coefficient of thermal expansion is less than the first coefficient of thermal expansion.

18. The package substrate of claim 13, further comprising
a second middle core laminated structure on a bottom surface of the second core laminate structure, the second core laminated structure being between the second surface of the core substrate and the second middle core laminated structure, the second middle core laminated structure including a plurality of fourth core insulating layers and a plurality of fourth core wiring layers on the plurality of fourth core insulating layers,
wherein the plurality of fourth core insulating layers have a fifth coefficient of thermal expansion, and
the fifth coefficient of thermal expansion is less than the second coefficient of thermal expansion.

19. A semiconductor package comprising:
a package substrate; and
a first semiconductor chip and a second semiconductor chip mounted on the package substrate,
wherein the package substrate includes,
a core substrate including a first surface and a second surface opposite to the first surface,
a first core laminated structure on the first surface of the core substrate, including a plurality of first core insulating layers and a plurality of first core wirings on the plurality of first core insulating layers, and including a first chip mounting space defined by the plurality of first core insulating layers,
a bridge chip within the first chip mounting space and including a bridge substrate and a bridge pad, and
a second core laminated structure on the second surface of the core substrate, and including a plurality of second core insulating layers and a plurality of second core wiring layers on the plurality of second core insulating layers, and
wherein the first core insulating layers have a first coefficient of thermal expansion, and the second core insulating layers have a second coefficient of thermal expansion less than the first coefficient of thermal expansion, and
the first semiconductor chip and the second semiconductor chip are electrically connected to each other through the bridge chip.

20. The semiconductor package of claim 19, wherein
a first portion of the bridge chip vertically overlaps the first semiconductor chip, and
a second portion of the bridge chip vertically overlaps the second semiconductor chip.
